(19) United States
(12) Patent Application Publication
(10) Pub. No.: US 2018/0225094 A1
(43) Pub. Date: Aug. 9, 2018

(54) RANDOM NUMBER GENERATING DEVICE AND RANDOM NUMBER GENERATING METHOD

(71) Applicant: RENESAS ELECTRONICS CORPORATION, Tokyo (JP)

(72) Inventor: Masami Nakajima, Tokyo (JP)

(21) Appl. No.: 15/835,115

(22) Filed: Dec. 7, 2017

(30) Foreign Application Priority Data
Feb. 7, 2017 (JP) 2017-020442

(51) Int. Cl. G06F 7/58; H01L 23/522; H01L 23/31

(52) U.S. Cl. CPC G06F 7/584; H01L 23/3142; H01L 23/5226

(57) ABSTRACT

To generate a random number with a larger number of bits and with reduced predictability, a random number generating device 1 includes a sensor 2 that measures a physical phenomenon, a seed value generator 3, and a random number generator 4. The seed value generator 3 generates a seed value for random number generation by using n bits (n is an integer from 1 to N) of an N-bit (N is an integer of 1 or more) digital value indicating a measured value of the sensor 2. The random number generator 4 generates an M-bit (M is an integer of more than n) random number by using the seed value generated by the seed value generator 3, with use of a predetermined pseudorandom number generation algorithm that generates a pseudorandom number with a larger number of bits than the number of bits of the seed value.

### CROSS-REFERENCE TO RELATED APPLICATIONS

This application is based upon and claims the benefit of priority from Japanese patent application No. 2017-020442, filed on Feb. 7, 2017, the disclosure of which is incorporated herein in its entirety by reference.

### BACKGROUND

The present invention relates to a random number generating device and a random number generating method and, for example, relates to a random number generating device and a random number generating method for generating random numbers using measured values of physical phenomena.

Examples of techniques to generate random numbers from measured values of physical phenomena include a technique disclosed in Japanese Unexamined Patent. Application Publication (Translation of PCT Application) No. 2005-526299. The random number generating device disclosed in this literature compresses a measured value of a sensor by a compression means, thereby reducing predictability. This random number generating device applies a hash function to a compressed digital value and thereby generates a random number.

### SUMMARY

However, the technique disclosed in Japanese Unexamined Patent Application Publication (Translation of POT Application) No. 2005-526299 compresses a measured value and calculates a hash value for the compressed value, and therefore the number of bits of a generated random number is small. Thus, it has been difficult to generate a random number that is hardly predictable and has a sufficient number of bits.

The other problems and novel features of the present invention will become apparent from the description of the specification and the accompanying drawings.

According to one embodiment, a random number generating device includes a seed value generator that generates a seed value for random number generation by using n bits (n is an integer from 1 to N) of an N-bit (N is an integer of 1 or more) digital value indicating a measured value of a physical phenomenon, and a random number generator that generates an M-bit (M is an integer of more than n) random number by using the seed value, with use of a predetermined pseudorandom number generation algorithm.

According to one embodiment described above, it is possible to reduce the predictability of a random number and increase the number of bits of a generated random number.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing an example of a configuration of a random number generating device according to an overview of an embodiment.

FIG. 2 is a block diagram showing a configuration example of a random number generating device according to a first embodiment.

FIG. 3 is a flowchart showing a flow of a random number generating operation in the random number generating device according to the first embodiment.

FIG. 4 is a schematic diagram showing a semiconductor device including a random number generating device according to a second embodiment.

### DETAILED DESCRIPTION

The following description and the attached drawings are appropriately shortened and simplified to clarify the explanation. In the figures, the identical reference symbols denote identical structural elements and the redundant explanation thereof is omitted.

### Overview of Embodiment

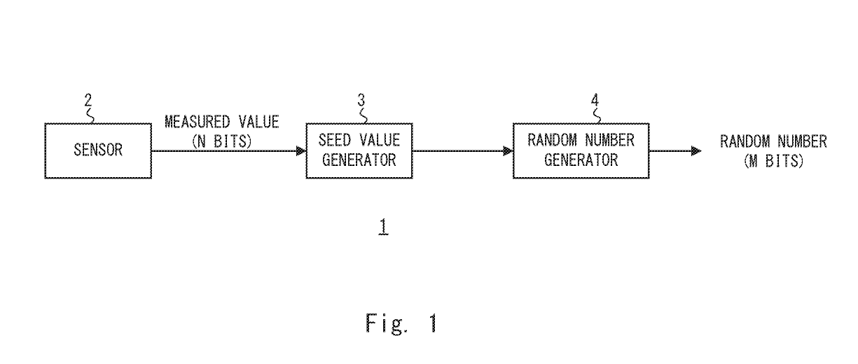

Prior to describing the details of an embodiment, an overview of an embodiment is described hereinafter. FIG. 1 is a block diagram showing one example of the configuration of a random number generating device 1 according to an overview of an embodiment. As shown in FIG. 1, the random number generating device 1 includes a sensor 2, a seed value generator 3, and a random number generator 4.

The sensor 2 is a sensor for measuring a physical phenomenon. Specifically, the sensor 2 is a sensor that measures a randomly varying physical quantity.

The seed value generator 3 generates a seed value for random number generation by using n bits of an N-bit digital value indicating a measured value of the sensor 2. N is an integer of 1 or more, and n is an integer from 1 to N. Thus, the seed value generator 3 may generate a seed value for random number generation by using all bits of a measured value or using some bits of a measured value.

The random number generator 4 generates an M-bit random number by using the seed value generated by the seed value generator 3, with use of a predetermined pseudorandom number generation algorithm. M is an integer of more than n. Note that the predetermined pseudorandom number generation algorithm may be any algorithm that can generate a pseudorandom number with a larger number of bits than the number of bits of the generated seed value.

As described above, in the random number generating device 1, the seed value generator 3 generates a seed value from a measured value of a randomly varying physical quantity. It is thereby possible to generate a seed value that is hardly predictable. Using this seed value, the random number generator 4 generates a random number with a larger number of bits than the number of bits used for the generation of the seed value. Therefore, according to the random number generating device 1, it is possible to reduce the predictability of a random number and increase the number of bits of a generated random number.

### First Embodiment

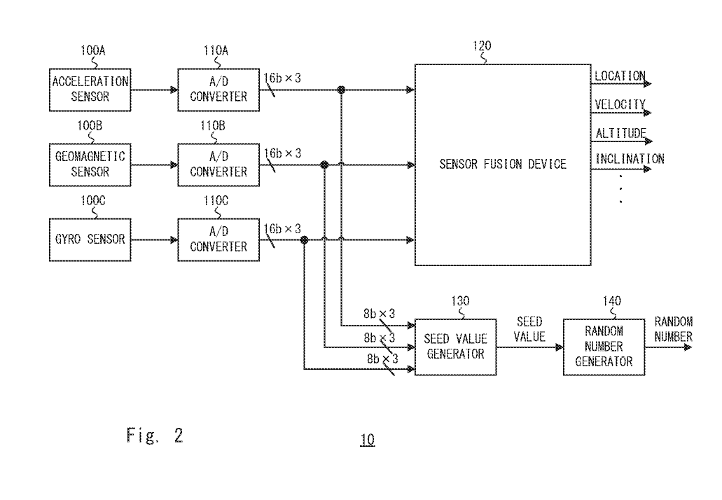

The details of an embodiment are described hereinafter. FIG. 2 is a block diagram showing a configuration example of a random number generating device 10 according to a first embodiment. As shown in FIG. 2, the random number generating device 10 includes an acceleration sensor 100A, a geomagnetic sensor 100B, a gyro sensor 100C, A/D converters 110A to 110C, a sensor fusion device 120, a seed value generator 130, and a random number generator 140.

As described above, in this embodiment, the random number generating device 10 includes a plurality of sensors, and the acceleration sensor 100A, the geomagnetic sensor 100B and the gyro sensor 100C correspond to the sensor 2 in FIG. 1. The acceleration sensor 100A is a sensor for detecting acceleration, and it outputs analog data of the detected acceleration to the A/D converter 110A. The geomagnetic sensor 100B is a sensor for detecting geomagnetism, and it outputs analog data of the detected geomagnetism to the A/D converter 110B. The gyro sensor 100C is a sensor for detecting angular velocity, and it outputs analog data of the detected angular velocity to the A/D converter 110C. Each of the acceleration sensor 100A, the geomagnetic sensor 100B and the gyro sensor 100C outputs detected values in three axes, i.e., the x-direction, the y-direction and the z-direction, as analog data.

The A/D converter 110A is an analog-to-digital converter that converts an analog value of the acceleration output from the acceleration sensor 100A into a digital value. In this embodiment, the A/D converter 110A converts an analog value in each axis into a 16-bit digital value and outputs it. All outputs from the A/D converter 110A are input to the sensor fusion device 120. Further, the outputs of the A/D converter 110A are input to the seed value generator 130. In this embodiment, digital values of detected values in the x-direction, the y-direction and the z-direction are input to the seed value generator 130 as one example. Particularly, in this embodiment, the low-order 8 bits of the 16-bit digital value that is a detected value in the x-direction, the low-order 8 bits of the 16-bit digital value that is a detected value in the y-direction, and the low-order 8 bits of the 16-bit digital value that is a detected value in the z-direction, each of which are output from the A/D converter 110A, are input to the seed value generator 130.

The A/D converter 110B is an analog-to-digital converter that converts an analog value of the geomagnetism output from the geomagnetic sensor 100B into a digital value. In this embodiment, the A/D converter 110B converts an analog value in each axis into a 16-bit digital value and outputs it. All outputs from the A/D converter 110B are input to the sensor fusion device 120. Further, the outputs of the A/D converter 110B are input to the seed value generator 130. In this embodiment, digital values of detected values in the x-direction, the y-direction and the z-direction are input to the seed value generator 130 as one example. Particularly, in this embodiment, the low-order 8 bits of the 16-bit digital value that is a detected value in the x-direction, the low-order 8 bits of the 16-bit digital value that is a detected value in the y-direction, and the low-order 8 bits of the 16-bit digital value that is a detected value in the z-direction, each of which are output from the A/D converter 110B, are input to the seed value generator 130.

The A/D converter 110C is an analog-to-digital converter that converts an analog value of the angular velocity output from the gyro sensor 100C into a digital value. In this embodiment, the A/D converter 110C converts an analog value in each axis into a 16-bit digital value and outputs it. All outputs from the A/D converter 110C are input to the sensor fusion device 120. Further, the outputs of the A/D converter 110C are input to the seed value generator 130. In this embodiment, digital values of detected values in the x-direction, the y-direction and the z-direction are input to the seed value generator 130 as one example. Particularly, in this embodiment, the low-order 8 bits of the 16-bit digital value that is a detected value in the x-direction, the low-order 8 bits of the 16-bit digital value that is a detected value in the y-direction, and the low-order 8 bits of the 16-bit digital value that is a detected value in the z-direction, each of which are output from the A/D converter 110C, are input to the seed value generator 130.

The sensor fusion device 120 is an arithmetic device composed of a CPU (Central Processing Unit), a DSP (Digital Signal Processor), a hardware computing unit or the like, and it carries out a predetermined operation on a measured value and outputs it to equipment in the subsequent stage, which is not shown. In this embodiment, the acceleration in each of the three axes converted into digital values by the A/D converter 110A, the geomagnetism in each of the three axes converted into digital values by the A/D converter 110B, and the angular velocity in each of the three axes converted into digital values by the A/D converter 110C are input to the sensor fusion device 120. The sensor fusion device 120 performs a predetermined operation by using the input current measured data, measured data in the past and the like, for example, and outputs various types of data such as location, velocity, altitude and inclination.

The seed value generator 130 and the random number generator 140 are described hereinafter. The random number generating device 10 generates a random number based on measured values of a physical phenomenon acquired from the acceleration sensor 100A, the geomagnetic sensor 100B and the gyro sensor 100C. Therefore, digital values of measured values are input not only to the sensor fusion device 120 but also to the seed value generator 130 as described above.

Note that, when transmitting output data from the sensor fusion device 120 to external equipment, for example, security technology such as challenge and response is sometimes used to protect the output data. When performing communication by challenge and response, a random number is required. The random number generating device 10 may generate a random number to be used for such communication, for example. Note that a random number generated by the random number generating device 10 may be applied to other uses.

The seed value generator 130 is a hardware circuit that generates a seed value for random number generation by using digital values of measured values of the acceleration sensor 100A, the geomagnetic sensor 100B and the gyro sensor 100C. The seed value generator 130 generates a seed value by using the low-order n bits (where n is an integer of 1 or more and less than N) of a measured value, which is a digital value of N (where N is an integer of 2 or more). To be specific, in this embodiment, the seed value generator 130 generates a seed value by using the low-order 8 bits of a 16-bit measured value in each of the x-direction, the y-direction and the z-direction of the acceleration sensor 100A, the low-order 8 bits of a 16-bit measured value in each of the x-direction, the y-direction and the z-direction of the geomagnetic sensor 100B, and the low-order 8 bits of a 16-bit measured value in each of the x-direction, the y-direction and the z-direction of the gyro sensor 100C.

The seed value generator 130 generates a bit sequence having an input digital value. To be specific, the seed value generator 130 generates, as a seed value, a bit sequence where input digital values are connected together, for example. Specifically, the seed value generator 130 connects the low-order 8 bits of a measured value of acceleration, the low-order 8 bits of a measured value of geomagnetism and the low-order 8 bits of a measured value of angular velocity together to generate a 72-bit sequence, and outputs it as a seed value to the random number generator 140. Thus, in this embodiment, by using the low-order n bits of a measured value of each of a plurality of sensors, the seed value generator 130 generates an m-bit seed value, where m is greater than n. Because the number of bits of a seed value is in inverse proportion to the frequency that a pseudorandom number to be generated appears again, as the number of bits of a seed value is greater, the predictability of a pseudorandom number to be generated is smaller.

Note that the seed value generator 130 may generate a seed value by another method. For example, the seed value generator 130 may generate a bit sequence having an input digital value, further perform compression or the like on the generated bit sequence and use it as a seed value. Further, a bit sequence having an input digital value may have a plurality of digital values that are input at different points of time in the time series.

The outputs of the acceleration sensor 100A, the geomagnetic sensor 100B and the gyro sensor 100C vary continuously due to the influence of a nearby person, object or the Earth and the like. Accordingly, irregular measured values are obtained from those sensors. This makes it difficult to predict the seed value that is output from the seed value generator 130.

The random number generator 140 generates an M-bit random number (where M is an integer of more than n in the above-described low-order n bits) by using the seed value generated by the seed value generator 130, with use of a predetermined pseudorandom number generation algorithm. In this embodiment, the random number generator 140 generates a 128-bit random number. The predetermined pseudorandom number generation algorithm may be an algorithm that generates a pseudorandom number with a larger number of bits than the number of bits of the seed value. To be specific, for example, the random number generator 140 may connect an m-bit seed value and a predetermined bit sequence to generate an M-bit sequence, input the M-bit sequence into a linear feedback shift register, which is a pseudorandom number generating circuit, and output, as a pseudorandom number, the M-bit sequence obtained after the shift is done k number of times (k is an integer of 1 or more). In this embodiment, to be specific, the random number generator 140 connects a 56 (=128−72)-bit sequence (e.g., a bit sequence where all bits are 1) as a predetermined bit sequence and an input 72-bit seed value to generate a 128-bit sequence, inputs the generated 128-bit sequence into a linear feedback shift register, outputs each bit of the linear feedback shift register after shift operation and thereby outputs a 128-bit pseudorandom number. In this case, however, because the bits of the random number generated initially are mostly 1, the predictability becomes high. Therefore, it is desirable not to use the value of the linear feedback shift register as a random number until the number of shifts reaches a predetermined number. The number of times the value is not used as a random number may be a fixed value (e.g., about 10 times) or a value obtained by use of a measured value or a seed value. Note that the above-described algorithm is one example, and a random number may be generated by another algorithm, not limited to the above example.

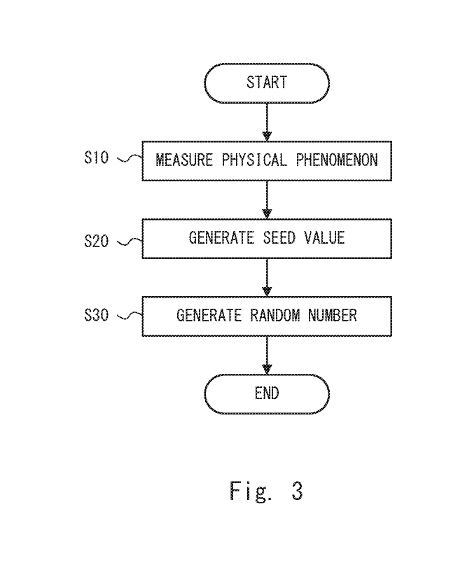

A random number generating operation in the random number generating device 10 is described hereinafter. FIG. 3 is a flowchart showing a flow of a random number generating operation in the random number generating device 10. The random number generating device 10 generates a random number by the following flow.

First, in Step 10 (S10), a physical phenomenon is measured by the acceleration sensor 100A, the geomagnetic sensor 100B and the gyro sensor 100C. A measured result is converted into a digital value by the A/D converters 110A, 110B and 110C and input to the seed value generator 130.

Next, in Step 20 (S20), the seed value generator 130 generates a seed value by using the input measured value.

After that, in Step 30 (S30), the random number generator 140 generates a random number by using the generated seed value.

The first embodiment is described above. In this embodiment, using a seed value that is hardly predictable, a random number with a larger number of bits than the number of bits used for the generation of the seed value is generated. Therefore, according to the random number generating device 10, it is possible to reduce the predictability of a random number and increase the number of bits of a generated random number.

Further, particularly, the seed value generator 130 generates a seed value by using the low-order a bits of a measured value. While the values of the high-order bits of measured values of the acceleration sensor 100A, the geomagnetic sensor 100B and the gyro sensor 100C are valid as sensing data, the values of the low-order bits are often treated as an error in general because a sensing result of a subtle change in each physical quantity is reflected thereon. However, this embodiment focuses attention on irregularity due to such a subtle change and uses it for the generation of a seed value. Therefore, although the number of bits to be used for the generation of a seed value is smaller than the total number of bits of a measured value, it is possible to generate a seed value that is hardly predictable. In other words, it is thereby possible to generate a random number that is hardly predictable. Note that, because a generated seed value is input to the random number generator 140 and a random number with a specified number of bits is generated, a small number of bits of a seed value causes no problem. The reduction of the number of bits required for the generation of a seed value leads to the reduction of the number of signal lines, which allows the reduction of the circuit size of the seed value generator 130 and the like. Thus, in this embodiment, by using only the predetermined low-order bits, not all bits, of a measured value for the generation of a seed value, it is possible to reduce the circuit size and generate a random number that is hardly predictable.

Furthermore, in this embodiment, a sensor measured value is input also to the seed value generator 130 and the sensor fusion device 120. Specifically, a sensor measured value is used not only for the generation of a seed value but also for predetermined processing other than the generation of a random number. Therefore, according to this embodiment, a random number can be generated only by adding the seed value generator 130 and the random number generator 140 to a device that performs predetermined processing by use of a sensor measured value. It is thereby possible to reduce the cost needed when adding the function of random number generation to an existing device.

Although the seed value generator 130 and the random number generator 140 are implemented by a hardware circuit in the above description of the embodiment, one or both of them may be implemented by software. Specifically they may be implemented by executing a program loaded to a memory by a processor.

Further, the aforementioned program can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto-optical disks), Compact Disc Read Only Memory (CD-ROM), CD-R, CD-R/W, and semiconductor memories (Such as mask ROM, Programmable ROM (PROM), Erasable PROM (EPROM), flash ROM, Random Access Memory (RAM), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

### Second Embodiment

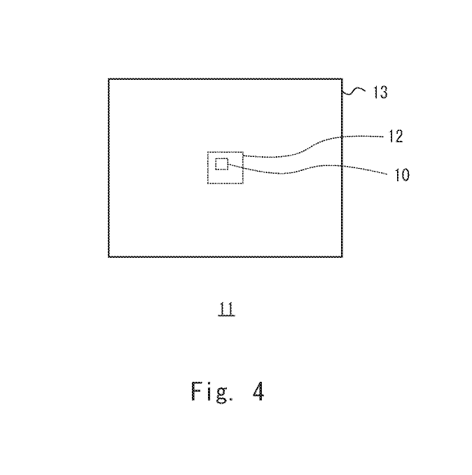

A second embodiment is described hereinbelow. In this embodiment, the elements of a random number generating device 10 are mounted on one semiconductor chip. FIG. 4 is a schematic diagram showing a semiconductor device 11 including a random number generating device 10 according to the second embodiment.

The semiconductor device 11 has a package 13 including a semiconductor chip 12. In the package 13, the semiconductor chip 12 is sealed by a sealant. The semiconductor chip 12 includes the random number generating device 10 according to the first embodiment. Specifically, the acceleration sensor 100A, the geomagnetic sensor 100B, the gyro sensor 100C, the A/D converters 110A, 110B and 110C, the seed value generator 130, the random number generator 140 and the sensor fusion device 120 are mounted on the same semiconductor chip 12. Note that the sensor fusion device 120 is not necessarily mounted on the same semiconductor chip.

In a device for generating a random number, there is a possibility that a seed value or a random number value could be hacked by detection of a signal line voltage or the like. With the recent trend toward finer design rules in semiconductor process, the signal line width has become smaller in semiconductor devices. Thus, in the semiconductor chip 12, the signal line of the random number generating device 10 is approximately 40 nm, for example. In this embodiment, because the elements of the random number generating device 10 are integrated in one semiconductor chip 12, it is possible to achieve a decrease in the signal line width of the random number generating device 10. It is thereby difficult to detect a voltage or the like from a signal line in this embodiment.

Further, in this embodiment, the semiconductor chip 12 is sealed by a sealant. Therefore, it is physically difficult to read a signal line.

The semiconductor chip 12 is preferably a semiconductor chip in a multi-layer interconnection structure. In the case where lines exist in a plurality of layers, it is necessary to cut away a surface wiring layer to detect a signal line in a wiring layer which is not a surface layer. However, if a wiring layer is cut away, the random number generating device 10 cannot operate, and it is not possible to detect the voltage or the like of the signal line of the random number generating device 10 in operation. Thus, when the semiconductor chip 12 has a multi-laver interconnection structure, it is possible to further reduce the risk of hacking.

Although the invention accomplished by the present inventor is specifically described using several embodiments in the foregoing, the present invention is not restricted to the above-described embodiments, and various changes and modifications may be made without departing from the scope of the invention. For example, sensors are not limited to an acceleration sensor, a geomagnetic sensor and a gyro sensor, and a sensor that measures another physical phenomenon may be used. Further, the number of sensors to be used is not limited to three, and it may be one or more. In the case where a seed value is generated from a measured value of one sensor, the seed value generator 130 may output an input digital value as a seed value.

Further, although measured values in the x-direction, the y-direction and the z-direction are used for the generation of a seed value in the above-described embodiment, a measured value in only one direction may be used. Further, any of those measured value may be used in combination.

Note that a specific number of bits described in the above embodiment is just one example, and the number of bits is not limited thereto.

The first and second embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A random number generating device comprising:
a sensor that measures a physical phenomenon;
a seed value generator that generates a seed value for random number generation by using n bits (n is an integer from 1 to N) of an N-bit (N is an integer of 1 or more) digital value indicating a measured value of the sensor; and
a random number generator that generates an M-bit (M is an integer of more than n) random number by using the seed value generated by the seed value generator, with use of a predetermined pseudorandom number generation algorithm that generates a pseudorandom number with a larger number of bits than the number of bits of the seed value.

2. The random number generating device according to claim 1, wherein
the measured value is an N-bit (N is an integer of 2 or more) digital value, and
the seed value generator generates the seed value by using low-order n bits is an integer of 1 or more and less than N) of the measured value.

3. The random number generating device according to claim 2, wherein
a plurality of sensors are included, and
the seed value generator generates the m-bit (m is an integer of more than n) seed value by using low-order n bits of the measured value of each of the plurality of sensors.

4. The random number generating device according to claim 1, wherein the sensor, the seed value generator and the random number generator are mounted on one semiconductor chip.

5. The random number generating device according to claim 4, wherein the semiconductor chip has a multi-layer interconnection structure.

6. The random number generating device according to claim 4, wherein the semiconductor chip is sealed by a sealant.

7. The random number generating device according to claim 1, wherein the measured value is used further for predetermined processing other than random number generation.

8. A random number generating method comprising:
measuring a physical phenomenon;
generating a seed value for random number generation by using n bits (n is an integer from 1 to N) of an N-bit (N is an integer of 1 or more) digital value indicating a measured value of the physical phenomenon; and
generating an M-bit (M is an integer of more than n) random number by using the generated seed value, with use of a predetermined pseudorandom number generation algorithm that generates a pseudorandom number with a larger number of bits than the number of bits of the seed value.

9. The random number generating method according to claim 8, wherein
the measured value is an N-bit (N is an integer of 2 or more) digital value, and
the seed value is generated by using low-order n bits (n is an integer of 1 or more and less than N) of the measured value.

10. The random number generating method according to claim 9, wherein
the m-bit (m is an integer of more than n) seed value is generated by using low-order n bits of each of a plurality of measured values.
